(19) United States
(12) Patent Application Publication
(10) Pub. No.: US 2015/0243548 A1
(43) Pub. Date: Aug. 27, 2015

(54) Control of FET Back-Channel Interface Characteristics

(71) Applicant: PEREGRINE SEMICONDUCTOR CORPORATION, San Diego, CA (US)

(72) Inventors: Anthony Mark Miscione, Ramona, CA (US); James S. Cable, Del Mar, CA (US)

(73) Assignee: PEREGRINE SEMICONDUCTOR CORPORATION, San Diego, CA (US)

(21) Appl. No.: 14/192,728

(22) Filed: Feb. 27, 2014

(51) Int. Cl. H01L 21/762; H01L 21/265; H01L 29/78

(52) U.S. Cl. CPC H01L 21/76251; H01L 29/78; H01L 21/265

(57) ABSTRACT

A method and structure for control of FET back-channel interface characteristics of an integrated circuit by implanting of selected implantation species at or near a device interface accessible during manufacture of the integrated circuit using layer transfer technology, without adversely affecting the structure or characteristics of a principal front-side FET.

### BACKGROUND

(1) Technical Field

This invention generally relates to electronic devices, and more specifically to field effect transistor (PET) devices.

(2) Background

FIG. 1 is a cross-sectional diagram of a typical prior art silicon-based PET. The illustrated FET includes a body or substrate 100 on which a buried oxide (BOX) layer 102 and an active device layer 104 are sequentially formed, in known fashion. The active device layer is typically a thin layer of suitably doped silicon, but may be of other materials as is known in the art. A Gate structure 106 is formed between a Source and a Drain and defines a channel 108 between the Source and Drain. The channel 108 is intentionally “doped” with selected ions to create desired characteristics for the PET. The substrate 100 includes a Body contact, which is often electrically connected to the Source. As is known in the art, the substrate 100 may be formed of a number of materials, including silicon, ceramic (e.g., silicon nitride, silicon carbide), precious or semiprecious crystalline or polycrystalline material such as diamond or sapphire, or other insulating or semi-insulating material.

In the structure of certain types of FETs, particularly silicon-on-insulator (SOI) based complementary metal oxide semiconductor (CMOS) devices, a parasitic back channel FET exists. The structure of the parasitic back channel FET is formed by the Source, substrate 100, BOX layer 102, and Drain. The substrate 100 acts as the gate for the parasitic back channel FET. FIG. 2 is an equivalent schematic diagram of the FET structure shown in FIG. 1. and shows how the parasitic back channel FET 200 is coupled in parallel to the principal FET 202.

An unwanted side effect of the parasitic back channel FET is that it can be strongly influenced by electrical fields that are created by back channel charge present at or near the interface 120 of the substrate 100 and the BOX layer 102, as well as by trapped charge within the BOX layer 102. The sources of such charge can be many, but are mainly due to the manufacturing process related to the construction of the substrate, construction of the FET devices themselves, or charging effects related to exposure of the FET devices to energetic irradiation such as high energy plasmas, x-rays, gamma rays, or cosmic radiation.

In order to mitigate the effects of such parasitic back channel FETs, typically “front-side” channel ion implantation techniques are used to control the electrical characteristics of the interface 120 of the substrate 100 and the BOX layer 102, particularly for SOI CMOS devices. This technique requires implanting ions into the active device layer 104 near the interface between the active device layer 104 and the BOX layer 102 before formation of the Gate structure 106. While economical and very compatible with standard fabrication processes, this technique has very severe limitations due to the inherent nature of ion species distribution characteristics when implanting through the entire active device layer 104 (which, as noted above, is typically a thin layer of silicon). This technique also has the inherent undesirable effect of altering the front-side interface characteristics as well as those of the “backside” interface 120, thus affecting the performance characteristics of the principal FET. Additionally, this technique limits the range of ion species available for implantation due to physical size of the implantation species or diffusion and activation characteristics. Another drawback of this technique is that physically large tons can impart severe mechanical damage in critical regions of the active device layer 104, which can degrade the overall electrical performance of the active FET device.

Accordingly, there is a need for a method and device structure that mitigate the effects of parasitic back channel FETs within FET devices without the drawbacks of conventional ion implantation. The present invention provides such a method and device structure.

### SUMMARY OF THE INVENTION

U.S. patent application Ser. No. 13/528,825 (Publication No. 20130154049A1, entitled “Integrated Circuits on Ceramic Wafers Using Layer Transfer Technology”, filed Jun. 20, 2012 and assigned to the assignee of the present invention), describes a layer transfer technology in which an integrated circuit (IC) device is fabricated in two or more parts that are then bonded together. In addition, other examples of layer transfer technologies are known in the art.

The present invention is based in part on the insight that such layer transfer technologies, when used in the manufacture of IC devices (particularly FETs based on SOI substrates), makes the insulator/active device layer interface easily accessible at an early stage of the IC wafer construction to perform ion implantation. Thus, in the manufacture of IC wafers utilizing layer transfer techniques, it is not necessary to implant through the thin active device layer utilized to manufacture the principal FET device in order to control the back channel interface, because there is a point in the various manufacturing processes before the actual bonding process where all of the interfaces are accessible for implantation.

The details of one or more embodiments of the invention are set forth in the accompanying drawings and the description below. Other features, objects, and advantages of the invention will be apparent from the description and drawings, and from the claims.

### DESCRIPTION OF THE DRAWINGS

FIG. 1 is a cross-sectional diagram of a typical prior art silicon-based FET.

FIG. 2 is an equivalent schematic diagram of the FET structure shown in FIG. 1.

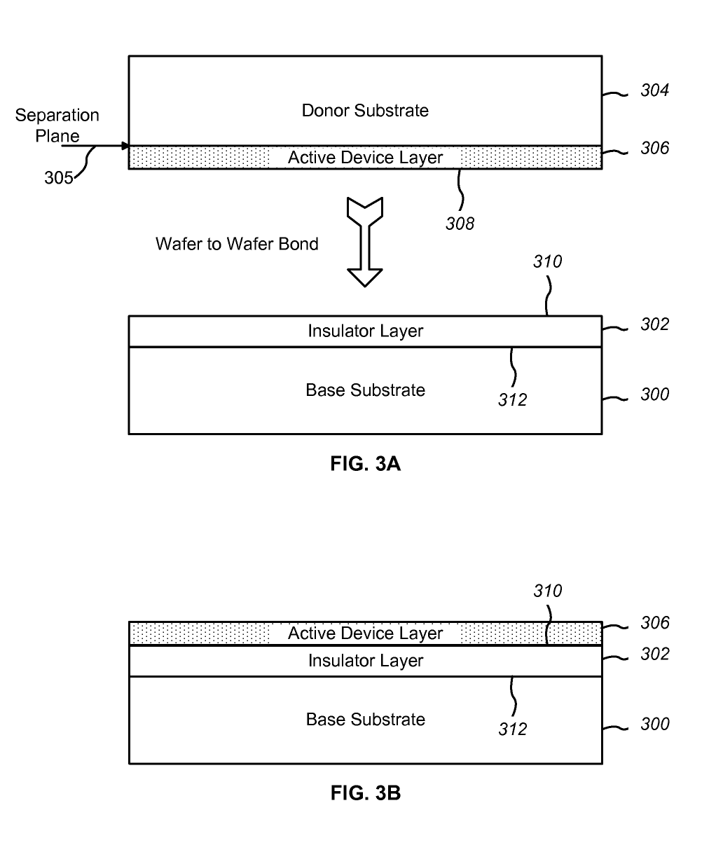

FIGS. 3A-3B are cross-sectional diagrams of a first embodiment of a FET device made in accordance with the present invention.

FIGS. 4A-4B are cross-sectional diagrams of a second embodiment of a FET device made in accordance with the present invention.

FIGS. 5A-5B are cross-sectional diagrams of a third embodiment of a FET device made in accordance with the present invention.

FIGS. 6A-6D are cross-sectional diagrams of a fourth embodiment of a FET device made in accordance with the present invention.

Like reference numbers and designations in the various drawings indicate like elements.

### DETAILED DESCRIPTION OF THE INVENTION

U.S. patent application Ser. No. 13/528,825 (Publication No. 20130154049A1, entitled “Integrated Circuits on Ceramic Wafers Using Layer Transfer Technology”, filed Jun. 20, 2012 and assigned to the assignee of the present invention), describes a layer transfer technology in which an integrated circuit (IC) device is fabricated in two or more parts that are then bonded together. In addition, other examples of layer transfer technologies are known in the art.

The present invention is based in part on the insight that such layer transfer technologies, when used in the manufacture of IC devices (particularly FETs based on SOI substrates), makes the insulator/active device layer interface easily accessible at an early stage of the IC water construction to perform ion implantation. Thus, in the manufacture of IC wafers utilizing layer transfer techniques, it is not necessary to implant through the active device layer utilized to manufacture the principal FET device in order to control the back channel interface, because there is a point in the various manufacturing processes before the actual bonding process where all of the interfaces are accessible for implantation.

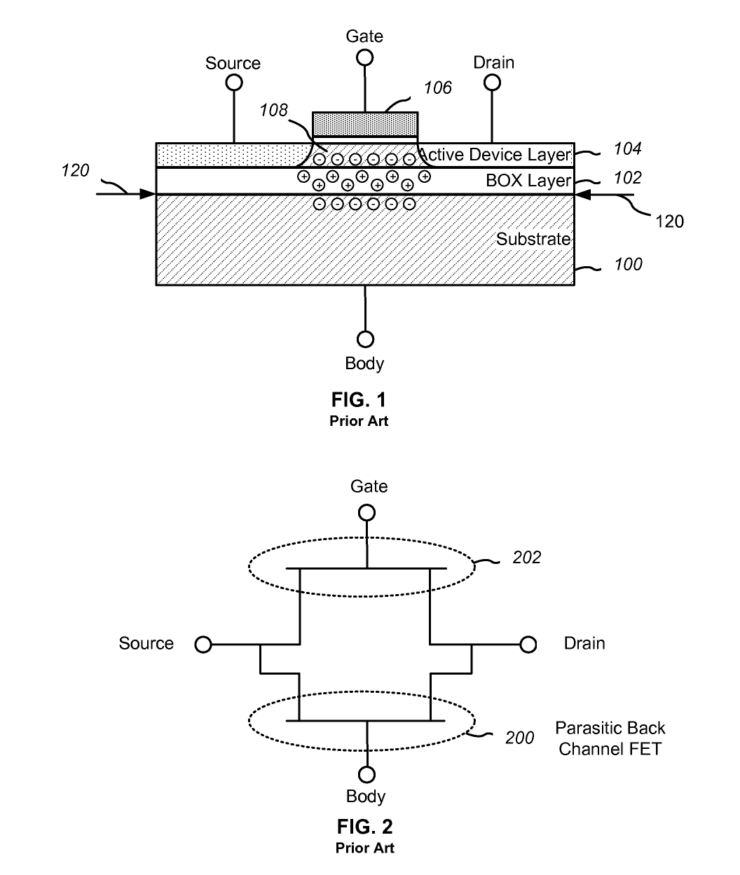

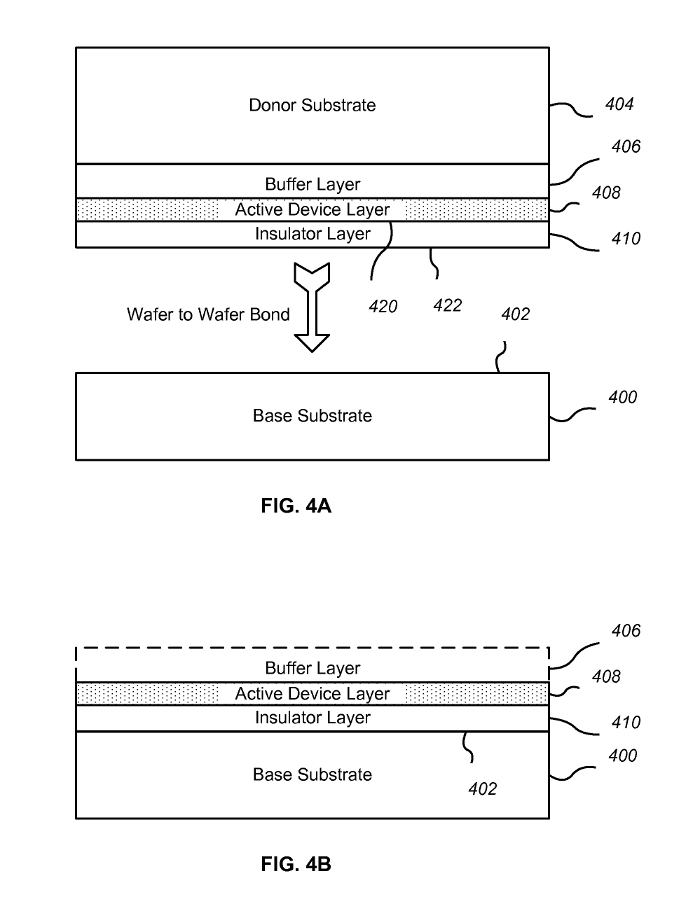

FIG. 3A is a cross-sectional diagram of a first embodiment of a FET device made in accordance with the present invention. In particular, FIG. 3A is an example of a base substrate 300 on which an insulator layer (e.g., buried oxide, or BOX) layer 302 is formed in conventional fashion. In the illustrated embodiment, the base substrate 300 is silicon, but it may be another material such as ceramic (e.g., silicon nitride, silicon carbide), precious or semiprecious crystalline or polycrystalline material such as diamond or sapphire (Al₂O₃), or other insulating or semi-insulating material A donor substrate 304 is used as a temporary support for an active device layer 306, which in this embodiment will eventually be attached to the insulator layer 302 (similar to the active device layer 104 in FIG. 1), such as by direct bonding. Subsequently, the bulk of the donor substrate 304 is separated from the active device layer 306 along a separation plane 305, such as by chemical or mechanical cleaving, etching, grinding, etc., in known fashion, as shown in FIG. 3B. The donor substrate 304 and the active device layer 306 may be of silicon or other semiconducting or semi-insulating material, including GaAs, InAlGaAs, GaN, or other so-called “III-V” materials. As used in this disclosure, the “active device layer” is a layer in which electronic device structures, such as FETs, have been fabricated or are to be fabricated at a later stage.

Since layer transfer technology allows a complete device structure to be fabricated in two parts, process steps can be performed on “outer” layers or exposed surfaces of such layers of either or both parts before they are bonded together. FIG. 3A shows which interfaces are available to he implanted before executing a wafer-to-wafer bond (i.e., donor substrate 304 to base substrate 300, including intervening layers). Such implantation may use any suitable technique, such as ion implantation or diffusion; however, ion implantation will be frequently preferred because it has the ability to cause mechanical changes to a targeted surface, as described below. For example, in the state shown in FIG. 3A, a desired implantation species can be implanted without passing through the active device layer 306 into the following interfaces or regions: at or within the surface 308 of the active device layer 306 that will become part of the backside channel 308; within the body of the insulator layer 302 itself; at or within the insulator/back-channel interface 310 (i.e., the exposed surface of the insulator layer 302); through the insulator layer 302 and at or near the insulator/base substrate interface 312 (i.e., the surface of the insulator layer 302 opposite the exposed surface of the insulator layer 302); or at or within the base substrate interface 312 before the insulator layer 302 is formed. More than one such interface or region may be implanted if desired.

Once the desired implantation is performed, the remaining conventional layer transfer technology manufacturing processes can be executed to complete the formation of the final fully bonded wafer, as shown in FIG. 3B. The final structure will be similar to that shown in FIG. 1, but without the drawback of having had to implant through the active device layer 306 utilized to manufacture the principal FET device or devices.

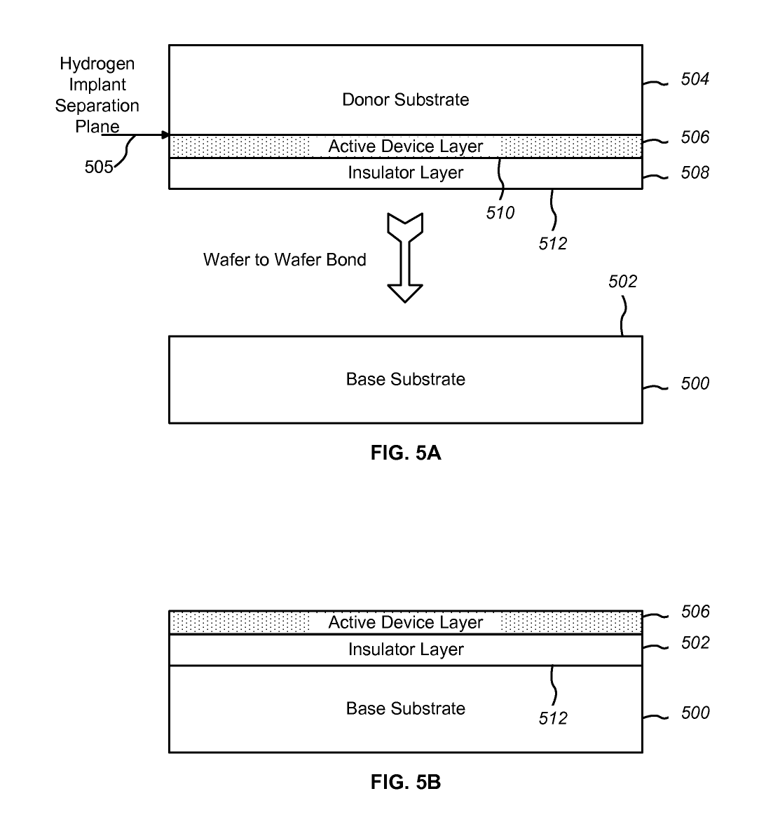

FIG. 4A is a cross-sectional diagram of a second embodiment of a FET device made in accordance with the present invention. In particular, FIG. 4A is an example of a base substrate 400 having an exposed surface 402. In the illustrated embodiment, the base substrate 400 may be a ceramic (e.g., silicon nitride, silicon carbide), precious or semiprecious crystalline or polycrystalline material such as diamond or sapphire, or other insulating or semi-insulating material. A donor substrate 404 is used as a temporary support for a buffer layer 406 (which may be silicon dioxide, for example), an active device layer 408, and an insulator layer 410. The insulator layer 410 will eventually be bonded to the base substrate 400, such as by direct bonding. Subsequently, the bulk of the donor substrate 404 is separated from the buffer layer 406, such as by chemical or mechanical cleaving, etching, grinding, etc., in known fashion, as shown in FIG. 4B. Optionally, the buffer layer 406 may also be removed using similar techniques, as shown in FIG. 4B (as indicated by dotted lines for the buffer layer 406). The donor substrate 404 and the active device layer 408 may be of any of the materials described for the corresponding layers in FIG. 3. One example of the materials and process steps shown in FIG. 4A and FIG. 4B (with the buffer layer 406 removed) is known as “bonded silicon-on-sapphire”, using a silicon-on-insulator donor substrate.

As is the case with the configuration state shown in FIG. 3A, in the configuration state shown in FIG. 4A, implantation may be performed before the bonding step to allow access to the desired interfaces for charge management. Thus, in the state shown in FIG. 4A, a desired implantation species can be implanted without passing through the active device layer 408 into the following interlaces or regions: through the insulator layer 410 and at or near the surface 420 of the active device layer 408 that will become part of the backside channel; within the body of the insulator layer 410; at or within the exposed surface 422 of the insulator layer 410; or at or within the base substrate interface 402. More than one such interface or region may be implanted if desired.

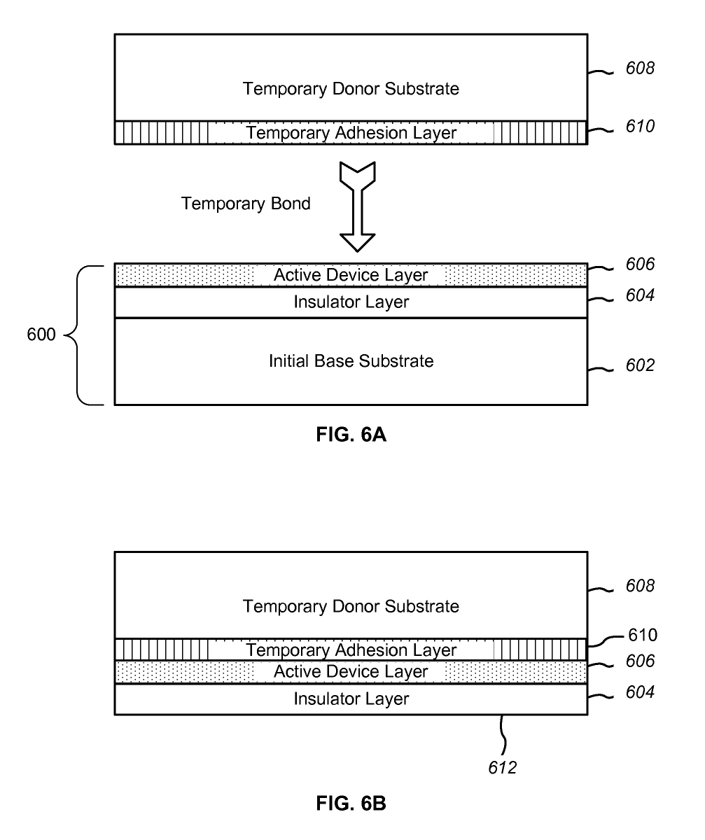

As another example, FIGS. 5A-5B are cross-sectional diagrams of a third embodiment of a FET device made in accordance with the present invention. In FIG. 5A, a base substrate 500 has an exposed surface 502. A donor substrate 504 is prepared in known fashion with a hydrogen implant defining a separation plane 505. The Implanted hydrogen forms a buried plane of microcavities parallel to the bonding interlace at the ion penetration depth (a process also known as “SmartCut”). The donor substrate 504 is used as a temporary support for an integral active device layer 506. An insulator layer 508 is formed on the exposed surface 510 of the active device layer 506. As in the embodiment shown in FIG. 3A and FIG. 3B, the insulator layer 508 will eventually be bonded to the base substrate 500, such as by direct bonding. Subsequently, the entire structure is heated, causing the implanted hydrogen to form micro-cracks along the separation plane 505 that eventually join together and split apart the upper part of the donor substrate 504 from the active device layer 506, resulting in the structure shown in FIG. 5B. In the illustrated embodiment, the base substrate 500 and donor substrate 504 may be made of any of the materials described above with respect to FIG. 3A. Additional steps may be employed, such as using chemical mechanical polishing (CMP) to smooth the exposed surface of active device layer 506.

As is the ease with the configuration state shown in the above embodiments, in the configuration state shown in FIG. 5A, implantation may be performed before the bonding step to allow access to the desired interfaces for charge management. Thus, in the state shown in FIG. 5A, a desired implantation species can be implanted without passing through the active device layer 506 into the following interfaces or regions: through the insulator layer 508 and at or near the surface 510 of the active device layer 506 that will become part of the backside channel; within the body of the insulator layer 508; at or within the exposed surface 512 of the insulator layer 508; or at or within the base substrate interface 502. More than one such interface or region may be implanted if desired.

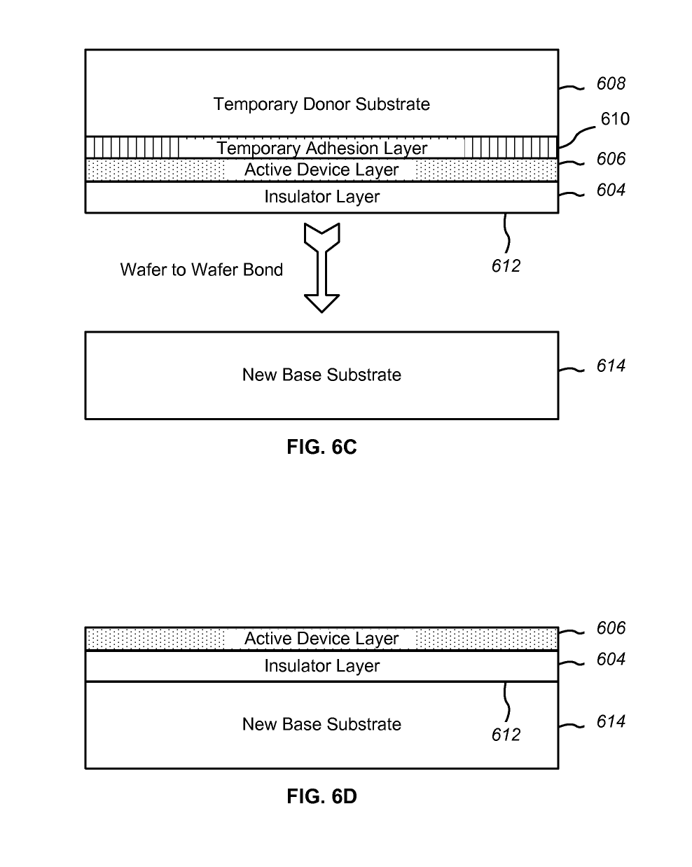

As yet another example, FIGS. 6A-6D are cross-sectional diagrams of a fourth embodiment of a FET device made in accordance with the present invention, utilizing a dual layer transfer procedure. In FIG. 6A, an intermediate structure 600 is formed in conventional fashion, comprising an initial base substrate 602, an insulator layer 604, and an active device layer 606. An example of such an intermediate structure 600 is a finished SOI wafer.

Subsequently, as shown in FIG. 6A, a temporary donor substrate 608 is adhered to the intermediate structure 600 by means of a temporary adhesion layer 610. In a subsequent step, as shown in FIG. 6B, the initial base substrate 602 is removed from the intermediate structure 600, such as by chemical or mechanical cleaving, etching, grinding, etc., in known fashion. In typical embodiments, the exposed surface of the insulator layer 604 is then smoothed, such as by chemical mechanical polishing (CMP).

At this point, implantation of selected materials may be made into the exposed surface 612 of the insulator layer 604, as described for the embodiments disclosed above. Again, such implantation does not require implanting through the active device layer 606.

Thereafter, as shown in FIG. 6C, the exposed surface 612 of the insulator layer 604 is direct bonded to a new base substrate 614, such as ceramic a (e.g., silicon nitride, silicon carbide), precious or semiprecious crystalline or polycrystalline material such as diamond or sapphire, or other insulating or semi-insulating material. As shown in FIG. 6D, the temporary donor substrate 608 and temporary adhesion layer 610 are then removed in known fashion, leaving a structure similar to that shown in FIG. 3B. (It should also be appreciated that the structures and process steps depicted in FIGS. 6C-6D are similar to those shown in FIGS. 4A-4B).

It should be appreciated that other layers may be formed on either the donor substrate or the base substrate before or after any of the layers shown in FIGS. 3A-3B, FIGS, 4A-4B, FIGS. 5A-5B. and FIGS. 6A-6D.

Without adversely affecting the structure or characteristics of a principal FET, the present invention enables modification of the electrical characteristics of an associated parasitic FET by either implanting dopant material at or within a desired interface (for example, by ion implantation or diffusion), or by implantation of selected ion species to impart mechanical damage at or within that interface that will change the electrical characteristics of the parasitic device through modification of the atomic bond structure of the interfacial layers; examples of such species include silicon, argon, nitrogen, and oxygen. In particular, the invention allows selection of a broad range of implantation species and desired implantation depths, and a more localized control of ion implantation that can be achieved without adversely affecting the front-side interface characteristics or damaging the active device layer of the principal FET. By way of example, implantations using the present invention can be used to modulate or improve device threshold voltage, breakdown voltage, carrier lifetimes, surface state, radiation hardness, etc. The invention can be practiced using standard IC fabrication and processing tools and processes.

Another aspect of the invention includes a method for control of FET back-channel interface characteristics during fabrication of an integrated circuit using a layer transfer process, the integrated circuit having at least an active device layer, including the step of implanting selected material at or within a FET back channel interface of the integrated circuit to control electrical characteristics of such interface without implanting such material through the active device layer.

Yet another aspect of the invention includes a method for control of FET back-channel interface characteristics of an integrated circuit, including the acts of:

Forming a donor substrate for an integrated circuit; forming at least one layer on the donor substrate, including an active device layer, the active device layer having a front side interface facing towards the donor substrate and a backside interlace facing away from the donor substrate; forming a base substrate for an integrated circuit; forming at least one layer on the base substrate, including an insulating layer, the insulating layer having a front side interface facing away from the base substrate and a backside interface facing towards the base substrate; implanting selected material at or within at least one of the backside interface of the active device layer or the front side interface of the insulating layer to control electrical characteristics of the implanted interface; bonding the backside interface of the active device layer to the front side interface of the insulating layer; and removing at least the donor substrate from all layers.

Still another aspect of the invention includes a method for control of FET back-channel interface characteristics of an integrated circuit, including the acts of:

Forming a donor substrate for an integrated circuit; forming at least one layer on the donor substrate, including an active device layer, the active device layer having a front side interface facing towards the donor substrate and a backside interlace facing away from the donor substrate; forming at least one layer on the backside interface of the active device layer, including an insulating layer having a front side interface facing towards the donor substrate and a backside interface facing away from the donor substrate; forming a base substrate for an integrated circuit, the base substrate having an exposed bonding interface; implanting selected material at or within at least one of the backside interlace of the insulating layer or the exposed bonding interface of the base substrate to control electrical characteristics of the implanted interface; bonding the backside interface of the insulating layer to the exposed bonding interface of the base substrate; and removing at least the donor substrate from all layers.

A number of embodiments of the invention have been described. It is to be understood that various modifications may be made without departing from the spirit and scope of the invention. For example, some of the steps described above may be order independent, and thus can be performed in an order different from that described. It is to be understood that the foregoing description is intended to illustrate and not to limit the scope of the invention, which is defined by the scope of the following claims, and that other embodiments are within the scope of the claims.

1. A method for control of FET back-channel interface characteristics during fabrication of an integrated circuit using a layer transfer process, the integrated circuit having at least an active device layer, including the step of implanting selected material at or within a FET back channel interface of the integrated circuit to control electrical characteristics of such interface without implanting such material through the active device layer.

2. (canceled)

3. A method for control of FET back-channel interface characteristics of an integrated circuit, including:
(a) forming a donor substrate for an integrated circuit;
(b) forming at least one layer on the donor substrate, including an active device layer, the active device layer having a front side interface facing towards the donor substrate and a backside interface facing away from the donor substrate;
(c) forming at least one layer on the backside interface of the active device layer, including an insulating layer having a front side interface facing towards the donor substrate and a backside interface facing away from the donor substrate;
(d) forming a base substrate for an integrated circuit, the base substrate having an exposed bonding interface;
(e) implanting selected material at or within at least one of the backside interface of the insulating layer or the exposed bonding interface of the base substrate to control electrical characteristics of the implanted interface;
(f) bonding the backside interface of the insulating layer to the exposed bonding interface of the base substrate; and
(g) removing at least the donor substrate from all layers.

4. (canceled)

5. (canceled)

6. (canceled)

7. (canceled)

8. (canceled)
